(19) United States
(12) Patent Application Publication
(10) Pub. No.: US 2011/0309468 A1
(43) Pub. Date: Dec. 22, 2011

(54) SEMICONDUCTOR CHIP PACKAGE AND METHOD OF MANUFACTURING THE SAME

(75) Inventors: Tae-young Oh, Seoul (KR); Kwang-il Park, Yongin-si (KR); Seung-jun Bae, Hwaseong-si (KR); Yun-seok Yang, Hwaseong-si (KR); Young-soo Sohn, Seoul (KR); Si-hong Kim, Yongin-si (KR)

(73) Assignee: SAMSUNG ELECTRONICS CO., LTD., Suwon-si (KR)

(21) Appl. No.: 13/088,442

(22) Filed: Apr. 18, 2011

(30) Foreign Application Priority Data
Jun. 17, 2010 (KR) 10-2010-0057570

(51) Int. Cl. H01L 23/58; H01L 21/58

(52) U.S. Cl. 257/508; 438/109; 257/E23.002; 257/E21.505

(57) ABSTRACT

A semiconductor chip package includes a substrate, a first layer disposed on the substrate and a second layer substantially similar to and disposed on the first layer. The first layer has a first input/output (I/O) circuit, a first through-via connected to the first input/output (I/O) circuit and a second through-via that is not connected to the first I/O circuit. The second layer has a second I/O circuit, a third through-via connected to the second I/O circuit and a fourth through-via that is not connected to the second I/O circuit. The first through-via is connected to the fourth through-via, and the second through-via is connected to the third through-via. The package maybe fabricated by stacking the layers, and changing the orientation of the second layer relative to the first to ensure that the first through-via is connected to the fourth through-via, and the second through-via is connected to the third through-via.

### PRIORITY STATEMENT

This application claims the benefit of Korean Patent Application No. 10-2010-0057570, filed on Jun. 17, 2010, in the Korean Intellectual Property Office.

### BACKGROUND

The inventive concept relate to a semiconductor chip package and to a method of fabricating the same. More particularly, the inventive concept relates to a 3D semiconductor chip package having a plurality of layers each including a silicon carrier body supporting an integrated circuit (IC) and an input/output (I/O) circuit electrically connected to the IC, and through-silicon vias (TSVs) extending through the carrier body.

The speed at which data communication is performed by a conventional semiconductor package containing semiconductor integrated circuits (ICs) is limited by the degree to which the ICs can be integrated, and the number of pins which can be provided in the package. Accordingly, stacking layers each including a semiconductor IC and an input/output (I/O) circuit connected to the IC, and providing an electrical interconnection using a through-silicon via (TSV) has been considered as a way to increase the transmission bandwidth without increasing the footprint of the package. However, when a plurality of layers each including a semiconductor IC are stacked, the input/output (I/O) circuits connected to a line of the TSVs may act as source of parasitic capacitance, thereby limiting the speed of transmission of data via the TSV line.

### SUMMARY

According to an aspect of the inventive concept, there is provided a semiconductor chip package comprising a first layer and a second layer disposed on the first layer, wherein the first layer includes a first carrier body, a first input/output (I/O) circuit, a first electrically conductive through-via extending through the first carrier body and electrically connected to the first input/output (I/O) circuit, and a second electrically conductive through-via extending through the first carrier body as electrically isolated from the first I/O circuit, wherein the second layer includes a second carrier body, a second input/output (I/O), a third electrically conductive through-via via extending through the second carrier body and electrically connected to the second I/O circuit, and a fourth electrically conductive through-via extending through the second carrier body as electrically isolated from the second I/O circuit, and wherein the first through-via is electrically connected to the fourth through-via, and the second through-via is electrically connected to the third through-via.

According to another aspect of the inventive concept, there is provided a semiconductor chip package comprising a plurality of layers stacked on a substrate, each of the layers including at least one I/O circuit, and a plurality of through-vias which form signal transmission lines connected to the I/O circuits, wherein the total number of I/O circuits connected to each signal transmission line is less than the total number of layers constituting the package. Each of the layers also includes a carrier body, and at least one semiconductor integrated circuit (IC) supported by the carrier body and to each of which a respective I/O circuit of the layer is electrically connected. In this respect, the circuits may be disposed at a surface of the carrier body. Furthermore, the electrically conductive through-vias of each layer extend through the carrier body of the layer as electrically isolated from one another. Also, the I/O circuit of each layer is electrically connected to a respective one of the through-vias of the layer, each of the through-vias of a layer is electrically connected to one of the through-vias of each of the other layers such that sets of the electrically connected through-vias constitute the signal transmission lines, respectively.

According to another aspect of the inventive concept, there is provided a method of fabricating a semiconductor chip package, comprising: forming first and second layers having substantially the same structures, and electrically connecting the first and second layers to each, wherein the first layer includes a carrier body, a first input/output (I/O) circuit of the package, and a semiconductor integrated circuit (IC) to which the first I/O circuit is electrically connected, wherein the second layer also includes a carrier body, a second input/output (I/O) circuit of the package, and a semiconductor integrated circuit (IC) to which the second I/O circuit is electrically connected, and wherein the first and second layers are electrically connected to each other by forming a plurality of through-vias through the carrier body of each layer such that one of the through-vias of each layer is connected to the I/O circuit of the layer whereas each other through-via of the layer is electrically isolated from the I/O circuit of the layer, such that the through-vias of the first layer are electrically connected to the through-vias of the second layer, respectively, and such that the through-via of the first layer that is electrically connected to the first I/O circuit is electrically connected to a through-via of the second layer that is electrically isolated from the second I/O circuit. This may be achieved by stacking the layers and changing the orientation of the second layer relative to the first before the second layer is stacked on the first layer.

### BRIEF DESCRIPTION OF THE DRAWINGS

Various aspects of the inventive concept will be more clearly understood from the following detailed description of preferred embodiments made in conjunction with the accompanying drawings in which:

FIG. 1 is a cross-sectional view of an embodiment of a semiconductor chip package according to the inventive concept;

FIG. 2 is a cross-sectional view of another embodiment of a semiconductor chip package according to the inventive concept;

FIG. 3 is an exploded perspective view of another embodiment of a semiconductor chip package according to the inventive concept;

FIG. 4 is an exploded perspective view of another embodiment of a semiconductor chip package according to the inventive concept;

FIG. 5 is an exploded perspective view of another embodiment of a semiconductor chip package according to the inventive concept;

FIG. 6 is an exploded perspective view of another embodiment of a semiconductor chip package according to the inventive concept;

FIG. 7 is a perspective view of another embodiment of a semiconductor chip package according to the inventive concept;

FIG. 8 is a schematic diagram of a semiconductor chip package according to the inventive concept;

FIG. 9 is a block diagram of a computing system according to the inventive concept;

FIG. 10 is a block diagram of a memory card according to the inventive concept; and

FIG. 11 is a flowchart of a method of fabricating a semiconductor chip package, according to the inventive concept.

### DETAILED DESCRIPTION OF THE PREFERRED EMBODIMENTS

Various embodiments and examples of embodiments of the inventive concept will be described more fully hereinafter with reference to the accompanying drawings. In the drawings, the sizes and relative sizes and shapes of elements and layers may be exaggerated for clarity. In particular, the cross-sectional illustrations of the devices are schematic.

Furthermore, spatially relative terms, such as “upper”, “lower”, “horizontal” and “vertical” are used to describe relationships as illustrated in the figures. The terms “clockwise” and “counterclockwise” generally refer to when viewed from above in the figures. Thus, the spatially relative terms may apply to orientations in use which differ from the orientation depicted in the figures. Obviously, though, all such spatially relative terms refer to the orientation shown in the drawings for ease of description and are not necessarily limiting as embodiments according to the inventive concept can assume orientations different than those illustrated in the drawings when in use.

It will also be understood that when an element or layer is referred to as being “on” or “connected to” another element or layer, it can be directly on or directly connected to the other element or layer or intervening elements or layers may be present. In contrast, when an element or layer is referred to as being “directly on” or “directly connected to” another element or layer, there are no intervening elements or layers present.

Furthermore, although the terms first, second, third etc. are used herein to describe various elements, layers, etc., these elements and/or layers are not limited by these terms. These terms are only used to distinguish one element or layer from another.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes. In addition, the term “structure” is generally used to encompass all characteristics of a particular component, namely, the constituent members of the component, and their relative dispositions, orientations, sizes and shapes. The term “connected” when used to describe a connection between conductive elements, such as vias, generally refers to an electrically conductive connection as the context of the description would make clear.

A first embodiment of a semiconductor chip package 100 according to the inventive concept will now be described in detail with reference to FIG. 1.

The semiconductor chip package 100 includes a semiconductor substrate 110, and a first layer 120 and a second layer 130 stacked on the semiconductor substrate 110. In an example of this embodiment, the first layer 120 is stacked directly on the semiconductor substrate 110, and the second layer 130 is stacked directly on the first layer 120, even though the figure shows some spacing therebetween for ease of illustration. The semiconductor substrate 110, the first layer 120, and the second layer 130 may be dies or wafers having integrated circuits (ICs), respectively. For example, the semiconductor substrate 110, the first layer 120, and the second layer 130 may be a die stack or a wafer stack. Alternatively, the semiconductor substrate 110 may be a wafer and the first and second layers 120 and 130 may be dies. That is, the semiconductor substrate 110 and the first and second layers 120 and 130 may be a die to wafer stack.

In this embodiment, the semiconductor substrate 110 has an insulating body, semiconductor integrated circuits (ICs) and first and second electrode pads 114 and 115 disposed on a top surface of the insulating body, and a plurality of conductive bumps 113 disposed on the bottom surface of the insulating body. In this respect, the insulating body, pads 114, 115, etc. may constitute a printed circuit board (PCB). The semiconductor ICs of the semiconductor substrate 110 are electrically connected to the semiconductor ICs of the first layer 120 and the second layer 130 via the first and second electrode pads 114 and 115, respectively, and are electrically connected to the conductive bumps 113. The conductive bumps 130 act as external terminals such that the semiconductor ICs of the package can be connected to other electronic devices. To this end, the conductive bumps 130 may be solder balls.

The first layer 120 also has an (first) input/output (I/O) circuit 122 connected to the IC of the first layer, a (first) through-via 127a that is connected to the input/output (I/O) circuit 122, and a (second) through-via 127b that is not connected to the I/O circuit 122. The first and second through-vias 127a and 127b are through-silicon vias (TSVs), in this example. The second layer 130 has an (second) I/O circuit 132a connected to the IC of the second layer, a (third) through-via 137a that is connected to the second I/O circuit 132, and a (fourth) through-via 137b that is not connected to the second I/O circuit 132. The third and fourth through-vias 137a and 137b are also TSVs in this example. That is, the first and second layers 120 and 130 may each comprise a silicon carrier body having conductive vias extending therethrough. The first through-via 127a (a via of the first layer 120) is connected to the fourth through-via 137b (a via of the second layer 130), and the second through-via 127b (another via of the first layer 120) is connected to the third through-via 137a (another via of the second layer 130).

Note, although FIG. 1 illustrates a semiconductor package in which the first layer 120 has two through-vias, and the second layer 130 has two through-vias, the semiconductor package 100 is illustrated in a simplified manner for ease of illustration and description, i.e., the inventive concept is not limited to the layers having any particular number of through-vias. In particular, a semiconductor chip package according to the inventive concept may, in practice, have several thousands of through-vias or more.

In one example of this embodiment of a semiconductor chip package according to the inventive concept, the first to fourth through-vias 127a, 127b, 137a, and 137b of the first and second layers 120 and 130 may together constitute a data bus, in which case semiconductor ICs of the first and second layers 120 and 130 receive or transmit data via the first to fourth through-vias 127a, 127b, 137a, and 137b. Also, in an example of this embodiment of the semiconductor chip package 100 according to the inventive concept, the semiconductor substrate 110 and the first and second layers 120 and 130 may be connected in a point-to-point manner to allow for free access to the first and second layers 120 and 130. In this case, the first to fourth through-vias 127a, 127b, 137a, and 137b may constitute a data bus or a command/address bus.

Each of the first and second I/O circuits 122 and 132 may include an input buffer and an output driver. Therefore, the first I/O circuit 122 may receive a signal from the outside and deliver the signal to the semiconductor IC of the first layer 120 via the first through-via 127a, and conversely may receive a signal from the semiconductor IC and deliver the signal to the outside via the first through-via 127a. Likewise, the second I/O circuit 132 may receive a signal from the outside and deliver the signal to the semiconductor IC of the second layer 130 via the third through-via 137a, and conversely may receive a signal from the semiconductor IC and deliver the signal to the outside via the third through-via 137a.

Referring still to FIG. 1, in this embodiment, the second layer 130 has the same structure as the first layer 120 but rotated 180° in a horizontal plane with respect to the first layer 120. Thus, the first through-via 127a of the first layer 120 is vertically aligned with the fourth through-via 137b in the second layer 130, and the second through-via 127b of the first layer 120 is vertically aligned with the third through-via 137a of the second layer 130.

As is clear from the description of the semiconductor chip package 100 above, with respect to the through-vias 127a and 137b (i.e., the through-vias that are located in the different layers but which are connected to each other), the first through-via 127a is connected to the first I/O circuit 122 but the fourth through-via 137b is not connected to the second I/O circuit 132. Likewise, with respect to the through-vias 127b and 137a, the third through-via 137a is connected to the second I/O circuit 132 but the second through-via 127b is not connected to the first I/O circuit 122. Thus, the second through-via 127b and the fourth through-via 137b are for bypassing their layers with received data or a command/address input thereto, and serve to join the first and second layers 120 and 130 to each other.

In other words, among the first and fourth through-vias 127a and 137b that are electrically connected to each other and the second and third through-vias 127b and 137a that are electrically connected to each other, only the first and third through-vias 127a and 137a are connected to I/O circuits in their respective layers. Even more specifically, in the semiconductor chip package 100, neither the line of connected first and fourth through-vias 127a and 137b nor the line of connected second and third through-vias 127b and 137a are connected to both the I/O circuit 122 of the first layer 120 and the I/O circuit 132 of the second layer 130. Thus, in the semiconductor chip package 100, parasitic capacitance generated due to the first and second I/O circuits 122 and 132 is minimized so as to maximize the transmission bandwidth of the data bus, for example, constituted by the first to fourth through-vias 127a, 127b, 137a, and 137b.

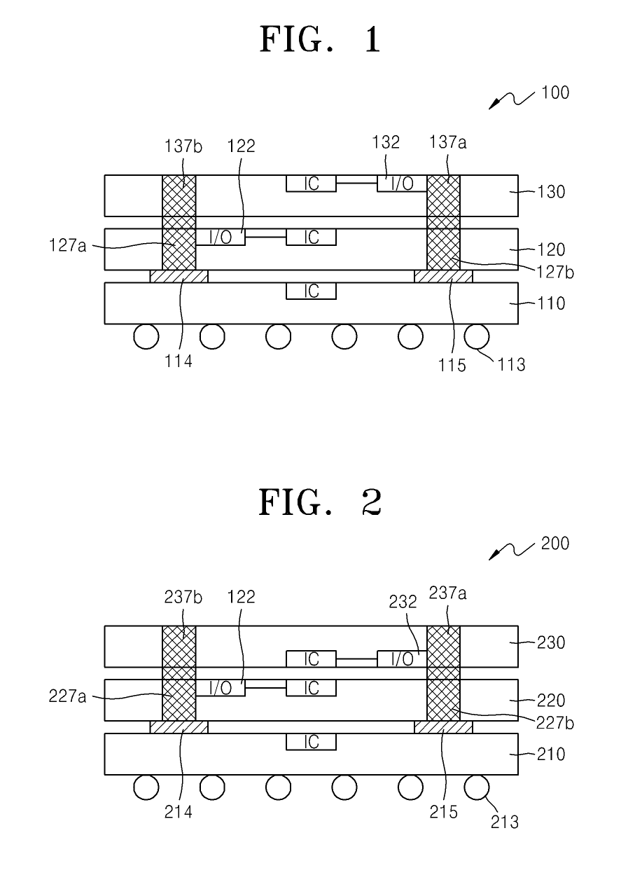

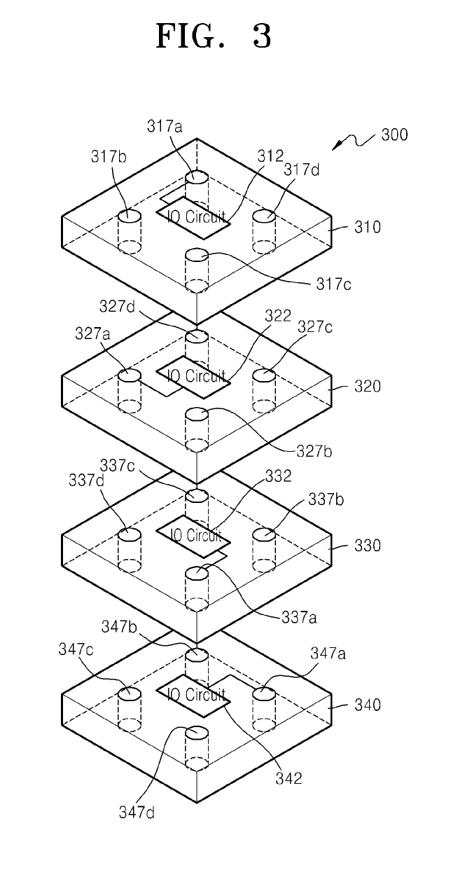

Another embodiment of a semiconductor chip package 200 according to the inventive concept will now be described with reference to FIG. 2.

The semiconductor chip package 200 includes a semiconductor substrate 210, a first layer 220, and a second layer 230. The first layer 220 is stacked directly on the semiconductor substrate 210 and the second layer 230 is stacked directly on the first layer 220. The semiconductor substrate 210 is similar to the semiconductor substrate 110 described above with reference to FIG. 1.

In this embodiment, the first layer 220 has a carrier body, a semiconductor IC supported by the carrier body, an (first) I/O circuit 222 also supported by the carrier body and connected to the IC, a (first) through-via 227a that extends through the carrier body and is connected to the first I/O circuit 222, and a (second) through-via 227b that extends through the carrier body but is not connected to the first I/O circuit 222. The first through-via 227a and the second through-via 227b are TSVs in the illustrated example of this embodiment. Thus, the overall structure of the first layer 220 is the same as that of the first layer 120 of the embodiment of FIG. 1.

The second layer 230 has a carrier body, a semiconductor IC supported by the carrier body, an (second) I/O circuit 232a also supported by the carrier body and connected to the IC, a (third) through-via 237a that extends through the carrier body and is connected to the second I/O circuit 232, and a (fourth) through-via 237b that also extends through the carrier body but is not connected to the second I/O circuit 232. The third and fourth through-vias 237a and 237b are also TSVs in this example.

Note, although FIG. 2 illustrates a semiconductor package in which the first layer 120 has two through-vias, and the second layer 130 has two through-vias, as was the case in the embodiment of FIG. 1, the semiconductor package 200 is illustrated in a simplified manner for ease of illustration and description, i.e., the inventive concept is not limited to any particular number of through-vias. In particular, a semiconductor chip package embodied according to the inventive concept illustrated in FIG. 2 may, in practice, have several thousands of through-vias or more.

In the semiconductor chip package 200, a data bus may be formed by the first to fourth through-vias 227a, 227b, 237a, and 237b, in which case semiconductor ICs of the first and second layers 220 and 230 receive or transmit data via the first to fourth through-vias 227a, 227b, 237a, and 237b. Also, in the semiconductor chip package 200, the semiconductor substrate 210 and the first and second layers 220 and 230 may be connected in a point-to-point manner to allow for free access to the first and second layers 220 and 230.

Each of the first and second I/O circuits 222 and 232 may include an input buffer and an output driver. In this case, the first I/O circuit 222 may receive a signal from the outside and deliver the signal to the first semiconductor IC of the first layer 220 via the first through-via 227a, and may conversely receive a signal from the first semiconductor IC and deliver the signal to the outside via the first through-via 227a. Likewise, the second I/O circuit 232 may receive a signal from the outside and deliver the signal to the second semiconductor IC of the second layer 230 via the third through-via 237a, and may conversely receive a signal from the second semiconductor IC and deliver the signal to the outside via the third through-via 237a.

Referring still to FIG. 2, in this embodiment the second layer 230 has the same structure as the first layer 220 but flipped over (i.e., rotated 180° about a horizontal axis). Accordingly, the I/O circuit 232 of the second layer 230 faces the first layer 220. Furthermore, the (first) through-via 227a of the first layer 220 is vertically aligned with the (fourth) through-via 237b of the second layer 230 and the (second) through-via 227b of the first layer 220 is vertically aligned with the (third) through-via 237a of the second layer 230.

Referring to FIG. 2, similar to the semiconductor chip package 100 of the embodiment of FIG. 1, of the first and fourth through-vias 227a and 237b that are connected to each other in the semiconductor chip package 200, the first through-via 227a is connected to the first I/O circuit 222 but the fourth through-via 237b is not connected to the second I/O circuit 232. Likewise, of the second and third through-vias 227b and 237a that are connected to each other, the third through-via 237a is connected to the second I/O circuit 232 but the second through-via 227b is not connected to the first I/O circuit 222. Therefore, the second through-via 227b and the fourth through-via 237b bypass their layers with received data or a command/address input thereto, and may be TSVs that serve to join the first and second layers 220 and 230 layers to each other.

Thus, similar to the embodiment of FIG. 1, in the semiconductor chip package 200, the connected through-vias (namely, the connected first and fourth through-vias 227a and 237b or the connected second and third through-vias 227b and 237a) are not connected to both the I/O circuit 222 of the first layer 220 and the second I/O circuit 232 of the second layer 230. Rather, of the connected first and fourth through-vias 227a and 237b, only the first through-via 227a is connected to an I/O circuit in the layer through which it extends. Likewise, of the connected second and third through-vias 227b and 237a, only the third through-via 237a is connected to an I/O circuit in the layer through which it extends. Accordingly, in the semiconductor chip package 200, parasitic capacitance generated due to the I/O circuits 222 and 232 of the layers 220 and 230 is minimized so as to maximize the transmission bandwidth of the data bus, for example, constituted by the first to fourth through-vias 227a, 227b, 237a, and 237b.

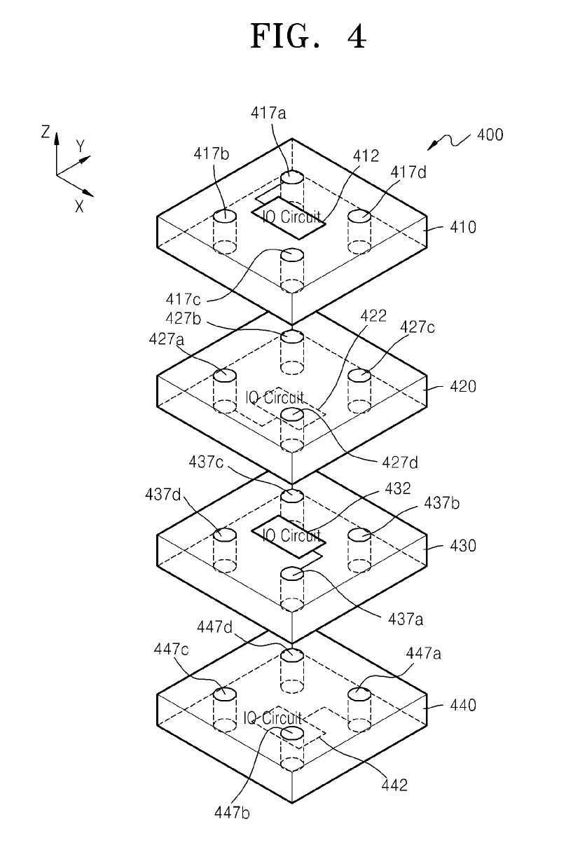

Another embodiment of a semiconductor chip package 300 according to the inventive concept will now be described with reference to FIG. 3.

The semiconductor chip package 300 includes a first layer 310, a second layer 320, a third layer 330, and a fourth layer 340. The fourth layer 340, the third layer 330, the second layer 320, and the first layer 310 may be stacked in the foregoing order (as illustrated) on a semiconductor substrate similar to the substrate 110 or 210 shown in FIGS. 1 and 2. However, the inventive concept is not so limited. Rather, the layers can be stacked one atop the other in different sequences. For instance, in another example of the embodiment of FIG. 3, the fourth layer 340, the second layer 320, the third layer 330, and the first layer 310 are stacked in the foregoing order on a semiconductor substrate.

Also, referring to FIG. 3, the first to fourth layers 310 to 340 are illustrated as being spaced apart from one another, but they may be stacked directly one atop the other in the semiconductor chip package 300 in a manner similar to that of the layers of the embodiments of the semiconductor chip packages 100 and 200 of FIGS. 1 and 2, i.e., the layers may be stacked without interposers therebetween. In this respect, the first to fourth layers 310 to 340 may each have the form of a rectangular parallelepiped, and may have the same dimensions (height, width and depth).

The semiconductor substrate and the first to fourth layers 310 to 340 may also be dies or wafers. For example, the semiconductor substrate and the first to fourth layers 310 to 340 may be a die stack or a wafer stack. Alternatively, the semiconductor substrate may be a wafer and the first to fourth layers 310 to 340 may be dies, in which case the semiconductor substrate and the first to fourth layers 310 to 340 constitute a die to wafer stack.

Each of the first to fourth layers 310 to 340 includes a carrier body, at least one semiconductor IC supported by the carrier body, at least one I/O circuit also supported by the carrier body and connected to the IC, and a plurality of through-vias extending through the carrier body. The IC (or ICs) is/are omitted from the figure (as well as those of the subsequently described embodiments) for clarity but reference may be made to FIGS. 1 and 2 for an illustration of the IC.

For example, the first layer 310 includes an I/O circuit 312 and first to fourth through-vias 317a, 317b, 317c, and 317d. Similarly, the second layer 320 includes an I/O circuit 322 and first to fourth through-vias 327a, 327b, 327c, 327d, the third layer 330 includes an I/O circuit 332 and first to fourth through-vias 337a, 337b, 337c, and 337d, and the fourth layer 340 includes an I/O circuit 343 and first to fourth through-vias 347a, 347b, 347c, and 347d. The through-vias may be TSVs. Furthermore, although FIG. 3 illustrates that each of the first to fourth layers 310 to 340 has only one I/O circuit and only four through-vias, the inventive concept is not so limited. Rather, each of the first to fourth layers 310 to 340 may include a plurality of I/O circuits and more than four through-vias.

In the illustrated example of this embodiment, the first through-via 317a of the first layer 310 is connected to the I/O circuit 312 of the first layer, and the second to fourth through-vias 317b to 317d are not connected to the I/O circuit 312. Thus, in this case, the second to fourth through-vias 317b to 317d are through-vias for bypassing their layers with received data or a command/address input thereto, and may be TSVs that serve to join the first to fourth layers 310 to 340 to each other. The I/O circuit 312 may include an input buffer and an output driver. Thus, the I/O circuit 312 may receive a signal from the outside and deliver the signal to a (first) semiconductor IC of the first layer 310 via the first through-via 317a, and conversely may receive a signal from the first semiconductor IC and deliver the signal to the outside via the first through-via 317a.

Each of the second to fourth layers 320 to 340 may have the same components/features as the first layer 310. That is, the first through-via 327a of the second layer 320 is connected to the I/O circuit 322, but the second to fourth through-vias 327b, 327c, and 327d are not connected to the I/O circuit 322. The first through-via 337a of the third layer 330 is connected to the I/O circuit 332, but the second to fourth through-vias 337b, 337c, and 337d are not connected to the I/O circuit 332. The first through-via 347a of the fourth layer 330 is connected to the I/O circuit 342, but the second to fourth through-vias 347b, 347c, and 347d are not connected to the I/O circuit 342. Therefore, the second to fourth through-vias 327b, 327c, 327d, 337b, 337c, 337d, 347b, 347c, and 347d bypass their layers with received data or a command/address input thereto, and may be TSVs that serve to join the first to fourth layers 310 to 340 to each other.

Furthermore, the structure of the second layer 320 may be the same as that of the first layer 310 but rotated 90° counterclockwise in a horizontal plane. In this case, therefore, the first through-via 317a of the first layer 310 is vertically aligned with the fourth through-via 327d of the second layer 320. Also, as illustrated in FIG. 3, the second to fourth through-vias 317b, 317c, and 317d of the first layer 310 are vertically aligned with the first to third through-vias 327a, 327b, and 327c, respectively, of the second layer 320.

Likewise, the structure of the third layer 330 may be the same as that of the first layer 310 but rotated 180° counterclockwise or clockwise in a horizontal plane. More specifically, the structure of the second layer 330 may be the same as that of the second layer 320 but rotated 90° counterclockwise in a horizontal plane. Therefore, in this case, the first through-via 327a of the second layer 320 is vertically aligned with the fourth through-via 337d of the third layer 330. Also, the second to fourth through-vias 327b, 327c, and 327d of the second layer 320 are vertically aligned with the first to third through-vias 337a, 337b, and 337c, respectively, of the third layer 330.

The structure of the fourth layer 340 may be the same that of the first layer 310 but rotated 270° counterclockwise in a horizontal plane. More specifically, the structure of the fourth layer 340 may be the same that of the third layer 330 but rotated 90° counterclockwise in a horizontal plane. Therefore, in this case, the structures of the first to fourth layers 310 to 340 are the same but the layers are oriented differently from each other in the package 300. Also, the first through-via 337a of the third layer 330 is vertically aligned with the fourth through-via 347d of the fourth layer 340 and likewise, the second to fourth through-vias 337b, 337c, and 337d of the third layer 330 are vertically aligned with the first to third through-vias 347a, 347b, and 347c, respectively, of the fourth layer 340.

Note, however, the orientations of the first to fourth layers 310 to 340 are not limited to those illustrated in FIG. 3. For example, in another example of the embodiment of FIG. 3, the structure of the second layer 320 is the same as that of the first layer 310 but rotated 270° counterclockwise in a horizontal plane, the structure of the third layer 330 is the same as that of the first layer 310 but rotated 180° counterclockwise or clockwise in a horizontal plane, and the structure of the fourth layer 340 is the same that of the first layer 310 but rotated 90° counterclockwise in a horizontal plane.

In any case, in the semiconductor chip package 300 of the embodiment of FIG. 3, only one of the (four) through-vias in each of the first to fourth layers 310 to 340 is connected to one of the I/O circuits 312 to 342. Furthermore, in each set of four through-vias which are connected to one another, only one through-via is connected to the I/O circuit of the layer in which it extends. For example, referring to FIG. 3, the first through-via 317a of the first layer 310, the fourth through-via 327d of the second layer 320, the third through-via 337c of the third layer 330, and the second through-via 347b of the fourth layer 340 are connected to one another. Among these through-vias, the first through-via 317a is connected to the I/O circuit 312 but the fourth through-via 327d, the third through-via 337c, and the second through-via 347b are not connected to the I/O circuits 322, 332, and 342, respectively.

Accordingly, each set of four through-vias that are connected to one another form a respective signal transmission line (conductive path) and hence, the I/O circuits 312, 322, 332, and 342 (and thus, the ICs) of the first to fourth layers 310 to 340 are connected to the substrate along four respective transmission lines. Thus, the number of I/O circuits connected to each of the four lines (one in this example) is less than the number of I/O circuit-containing layers (four) through which the lines extend (to the substrate) in the package. This contrasts with the case of a conventional semiconductor chip package in which each through-via of a layer is connected to an I/O circuit of that layer. Thus, in the embodiment of FIG. 3 the number of I/O circuits connected to each transmission line is ¼ of the number of I/O circuits that would be connected to a transmission line in a corresponding semiconductor chip package having conventional TSV architecture.

Furthermore, as was mentioned above, each of the first to fourth layers 310, 320, 330, and 340 may include a plurality of I/O circuits. In this case, the number of through-vias of each layer still exceeds the number of I/O circuits of the layer, and respective ones of the through-vias of each layer are connected to the I/O circuits of the layer. For example, referring to FIG. 3, each of the first to fourth layers 310 to 340 may include two I/O circuits, and the first through-via 317a, 327a, 337a, or 347a and the second through-via 317b, 327b, 337b, or 347b of each layer may be connected to the two I/O circuits, respectively, of the layer. Thus, comparing this example of the embodiment of FIG. 3 with a corresponding conventional semiconductor chip package, the number of I/O circuits connected to each signal transmission line is cut in half.

Accordingly, in an embodiment of a semiconductor chip package according to the inventive concept as illustrated in FIG. 3, parasitic capacitance generated due to the I/O circuits 312 to 342 is less than that which would be generated in a corresponding semiconductor chip package having conventional TSV architecture, and the transmission bandwidth of a data bus constituted by the first to fourth through-vias 317a to 347d is comparatively greater.

Another embodiment of a semiconductor chip package 400 according to the inventive concept will now be described with reference to FIG. 4.

The semiconductor chip package 400 includes a first layer 410, a second layer 420, a third layer 430, and a fourth layer 440. The fourth layer 440, the third layer 430, the second layer 420, and the first layer 410 are stacked on a semiconductor substrate similar to the substrate of the embodiments of FIGS. 1 and 2. Also, the semiconductor substrate and the first to fourth layers 410 to 440 may be dies or wafers as described above.

In the semiconductor chip package 400 of FIG. 4, each of the first to fourth layers 410, 420, 430, and 440 includes a carrier body, at least one semiconductor IC supported by the carrier body, at least one I/O circuit also supported by the carrier body and connected to the IC, and a plurality of through-vias, similar to the embodiment of the semiconductor chip package 300 of FIG. 3. For example, the first layer 410 includes an I/O circuit 412 and first to fourth through-vias 417a, 417b, 417c, and 417d. Similarly, the second layer 420 includes an I/O circuit 422 and first to fourth through-vias 427a, 427b, 427c, 427d, the third layer 430 includes an I/O circuit 432 and first to fourth through-vias 437a, 437b, 437c, and 437d, and the fourth layer 440 includes an I/O circuit 443 and first to fourth through-vias 447a, 447b, 447c, and 447d. The through-vias may be TSVs. Also, the first to fourth layers 410 to 440 are illustrated in FIG. 4 as being vertically spaced apart from one another for ease of illustration, but the first to fourth layers 410 to 440 may be stacked directly on one another in a manner similar to the layers of the semiconductor chip packages 100 and 200 of the embodiments of FIGS. 1 and 2, i.e., without the intermediary of interposers between the layers.

In the illustrated example of this embodiment, the first through-via 417a of the first layer 410 is connected to the I/O circuit 412 of the first layer 410, but the second to fourth through-vias 417b, 417c, and 417d of the first layer 410 are not connected to the I/O circuit 412. Accordingly, the second to fourth through-vias 417b to 417d bypass received data or a command/address input thereto, and may be TSVs that serve to join the first to fourth layers 410 to 440 to each other.

The I/O circuit 412 may include an input buffer and an output driver. Thus, the I/O circuit 412 may receive a signal from the outside and deliver the signal to the semiconductor IC of the first layer 410 via the first through-via 417a, and conversely may receive a signal from the semiconductor IC of the first layer 410 and deliver the signal to the outside via the first through-via 417a.

Likewise, the first through-via 427a of the second layer 420 is connected to the I/O circuit 422, but the second to fourth through-vias 427b, 427c, and 427d of the second layer 420 are not connected to the I/O circuit 422. The first through-via 437a of the third layer 430 is connected to the I/O circuit 432, but the second to fourth through-vias 437b, 437c, and 437d of the third layer 430 are not connected to the I/O circuit 432. The first through-via 447a of the fourth layer 427 is connected to the I/O circuit 442, but the second to fourth through-vias 447b, 447c, and 447d of the fourth layer 427 are not connected to the I/O circuit 442. Thus, the second to fourth through-vias 427b, 427c, 427d, 437b, 437c, 437d, 447b, 447c, and 447d bypass their layers with received data or a command/address input thereto, and may be TSVs that serve to join the first to fourth layers 410 to 440 to each other.

Also, in this example of the embodiment of FIG. 4, the structure of the second layer 420 is the same as that of the first layer 410 but flipped over, i.e., rotated 180° about a horizontal axis (the X-axis in the figure). Therefore, the first through-via 417a of the first layer 410 is vertically aligned with the second through-via 427b of the second layer 420. Likewise, the second to fourth through-vias 417b, 417c, and 417d of the first layer 410 are vertically aligned with the first through-via 427a, the fourth through-via 427d, and the third through-via 427c of the second layer 420, respectively.

Also, in this example, the structure of the third layer 430 is the same as that of the first layer 410 but rotated 180° counterclockwise or clockwise in a horizontal plane (the X-Y plane in the figure). Therefore, the first through-via 427a of the second layer 420 is vertically aligned with the fourth through-via 437d of the third layer 430 and likewise, the second to fourth through-vias 427b, 427c, and 427d of the second layer 420 are vertically aligned with the third, second, and first through-vias 437c, 437b, and 437a of the third layer 430, respectively.

Finally, in this example, the structure of the fourth layer 440 is the same as that of the first layer 410 but flipped over, i.e., is rotated 180° about a horizontal axis (in this case, a Y-axis perpendicular to the X-axis). Therefore, the first through-via 437a of the third layer 430 is vertically aligned with the second through-via 447b of the fourth layer 440 and likewise, the second to fourth through-vias 437b, 437c, and 437d of the third layer 430 are vertically aligned with the first through-via 447a, the fourth through-via 447d, and the third through-via 447c of the fourth layer 440, respectively.

Accordingly, the first through-via 417a of the first layer 410, the second through-via 427b of the second layer 420, the third through-via 437c of the third layer 430, and the fourth through-via 447d of the fourth layer 440 are connected to one another. Of these through-vias, the first through-via 417a is connected to the I/O circuit 412, whereas the second through-via 427b, the third through-via 437c, and the fourth through-via 447d are not be connected to the I/O circuits 422, 432, and 442, respectively, of their layers. Similarly, only one through-via, of each other set of four through-vias that are connected to one another, is connected to one of the I/O circuits 412 to 442. As was described above in connection with the embodiment of FIG. 3, each such set of four through-vias that are connected to one another form a respective conductive path extending through the layers to the semiconductor substrate. Accordingly, four respective signal transmission lines extend through the first to fourth layers 410 to 440 as electrically isolated from one another, and the four transmission lines are connected to the I/O circuits 412, 422, 432, and 442 of the first to fourth layers 410 to 440, respectively.

In the illustrated example, as described above, each set of four connected through-vias is connected to a respective one of the I/O circuits 412, 422, 432, and 442. Thus, in the semiconductor package 400, the number of I/O circuits (one) connected to each transmission line (connected through-vias) is less than the total number of layers (four). Accordingly, the number of I/O circuits connected to a transmission line in the semiconductor chip package 400 is ¼ the number of I/O circuits that would be connected to a transmission line in a semiconductor chip package having conventional TSV architecture. Accordingly, in the semiconductor chip package 400, parasitic capacitance generated due to the I/O circuits 412 to 442 is minimized to maximize the transmission bandwidth of a data bus, for example, formed by the first to fourth through-vias 417a to 447d. Also, the number of I/O circuits of each of the first to fourth layers 410 to 440 is less than that in a corresponding semiconductor chip package having conventional TSV architecture.

Therefore, the embodiment of FIG. 4 provides the same advantages as the embodiment of FIG. 3, and encompasses variations similar to those described above with respect to the illustrated example of the embodiment of FIG. 3.

Specifically, as to these variations, the inventive concept is not limited to the orientation of the first to fourth layers 410 to 440 illustrated in FIG. 4. For example, in another example of the semiconductor chip package 400 according to the inventive concept, the structure of the second layer 420 is the same as that of the first layer 410 but flipped over about the Y-axis, the structure of the third layer 430 is the same as that of the first layer 410 but rotated 180° counterclockwise or clockwise in a horizontal plane, and the structure of the fourth layer 440 is the same as that of the first layer 410 but flipped over about the X-axis.

In another example of the semiconductor chip package 400, the structure of the second layer 420 is the same as that of the first layer 410 but rotated 90° counterclockwise in a horizontal plane, the structure of the third layer 430 is the same as that of the first layer 410 but rotated 180° counterclockwise or clockwise in a horizontal plane, and the structure of the fourth layer 440 is the same as that of the first layer 410 but flipped over about the Y-axis.

In still another example of the semiconductor chip package 400 according to the inventive concept, the fourth layer 440, the second layer 420, the third layer 430, and the first layer 410 are stacked in the foregoing order.

Also, in the illustrated example of the semiconductor chip package 400, each of the layers has only one I/O circuit, and with respect to each of the sets of four connected through-vias, only one of the connected through-vias is connected to an I/O circuit. Alternatively, each of the first to fourth layers 410 to 440 may include a plurality of I/O circuits as long as the number of through-vias of each layer still exceeds the number of I/O circuits of the layer. In this case, respective ones of the through-vias of each layer are connected to the I/O circuits of the layer.

For example, referring to FIG. 4, each of the first to fourth layers 410 to 440 may include two I/O circuits, and the first through-via 417a, 427a, 437a, or 447a and the second through-via 417b, 427b, 437b, or 447b of each layer may be connected to two I/O circuits, respectively, of the layer. Thus, comparing this example of the embodiment of FIG. 4 with a corresponding conventional semiconductor chip package, the number of I/O circuits connected to each signal transmission line is cut in half.

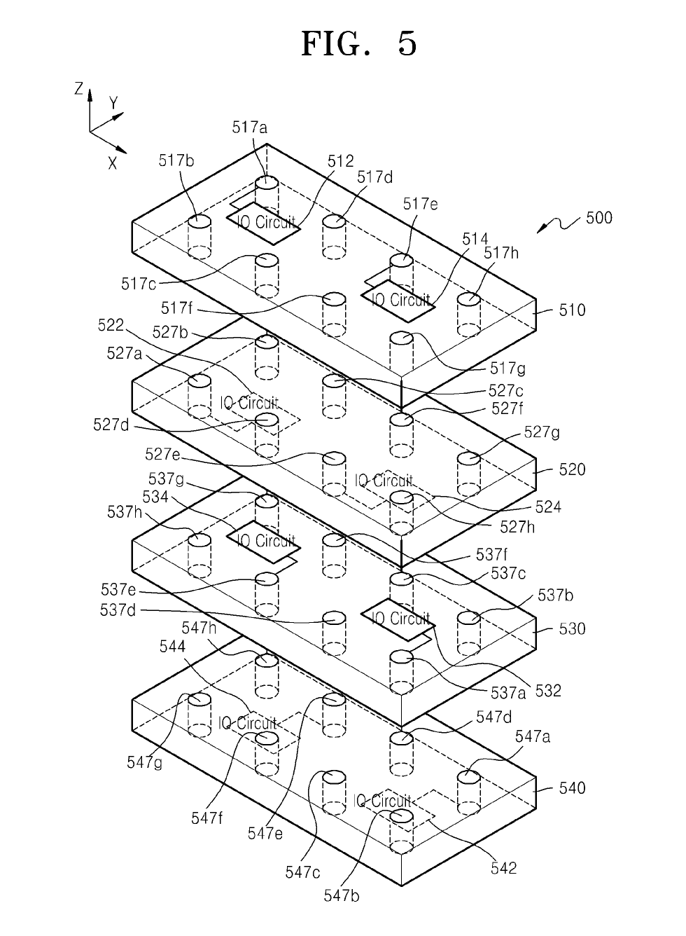

Another embodiment of a semiconductor chip package 500 according to the inventive concept will now be described with reference to FIG. 5.

The semiconductor chip package 500 includes a first layer 510, a second layer 520, a third layer 530, and a fourth layer 540. The fourth layer 540, the third layer 530, the second layer 520, and the first layer 510 may be stacked in the foregoing order on a semiconductor substrate of the type shown in and described above with reference to FIGS. 1 and 2.

The semiconductor substrate and the first to fourth layers 510 to 540 may be dies or wafers. For example, the semiconductor substrate and the first to fourth layers 510 to 540 may be a die stack or a wafer stack. Alternatively, the semiconductor substrate may be a wafer and the first to fourth layers 510 to 540 may be dies, in which case the semiconductor substrate and the first to fourth layers 510 to 540 constitute a die to wafer stack.

Each of the first to fourth layers 510 to 540 includes a carrier body, a semiconductor integrated circuit (IC) supported by the carrier body, at least one I/O circuit also supported by the carrier body and connected to the IC, and a plurality of through-vias. FIG. 5 illustrates that each of the first to fourth layers 510 to 540 includes two I/O circuits and eight through-vias, but the inventive concept is not so limited. Rather, each of the first to fourth layers 510 to 540 may include more than two I/O circuits and a greater number of through-vias.

Also, referring to FIG. 5, the first to fourth layers 510 to 540 are illustrated as being vertically spaced apart from one another for ease of illustration, but the layers may be stacked in the semiconductor chip package 500 in a manner similar to that of the layers of the embodiments of the semiconductor chip packages 100 and 200 of FIGS. 1 and 2, i.e., the layers may be stacked without interposers therebetween.

A first through-via 517a of the first layer 510 is connected to a first I/O circuit 512 of the first layer 510, and a fifth through-via 517e of the first layer 510 is connected to a second I/O circuit 514 of the first layer 510. Also, the second to fourth through-vias 517b, 517c, and 517d and the sixth to eighth through-vias 517f, 517g, and 517h of the first layer 510 are not connected to either the first or second I/O circuit 512 or 514. The first to eighth through-vias 517a to 517h may be TSVs. Thus, the second to fourth through-vias 517b, 517c, and 517d and the sixth to eighth through-vias 517f, 517g, and 517g bypass received data or a command/address input thereto, and may be TSVs that serve to join the first to fourth layers 510 to 540 to each other.

Each of the first and second I/O circuits 512 and 514 may include an input buffer and an output driver. The first and second I/O circuits 512 and 514 thus function in the manner described above with reference to the embodiments of FIGS. 1 to 4.

The second to fourth layers 520 to 540 have the same components as the first layer 510. Specifically, the second layer 520 includes a first through-via 527a connected to a first I/O circuit 522, and a fifth through-via 527e connected to a second I/O circuit 524. The third layer 530 includes a first through-via 537a connected to a first I/O circuit 532, and a fifth through-via 537e connected to a second I/O circuit 534. The fourth layer 540 includes a first through-via 547a connected to a first I/O circuit 542, and a fifth through-via 547e connected to a second I/O circuit 544. Also, second to fourth through-vias 527b, 527c, 527d, 537b, 537c, 537d, 547b, 547c, and 547d and sixth to eighth through-vias 527f, 527g, 527h, 537f, 537g, 537h, 547f, 547g, and 547h of the second to fourth layers 520 to 540 are not be connected to I/O circuits 522, 524, 532, 534, 542, and 544. The first to fourth through-vias 517a to 547h may be TSVs. Thus, the second to fourth through-vias 527b, 527c, 527d, 537b, 537c, 537d, 547b, 547c, and 547d, and the sixth to eighth through-vias 527f, 527g, 527h, 537f, 537g, 537h, 547f, 547g, and 547h bypass received data or a command/address input thereto, and may be TSVs that serve to join the first to fourth layers 510 to 540 to each other.

With respect to the orientation of the layers, the structure of the second layer 520 may be the same as that of the first layer 510 but flipped over about a horizontal axis (X-axis in the figure). Also, the structure of the third layer 530 may be the same as that of the first layer 510 but rotated 180° counterclockwise or clockwise in a horizontal plane (X-Y plane in the figure). The structure of the fourth layer 540 may be the same as that of the first layer 510 but flipped over about a horizontal axis perpendicular to the aforementioned X-axis, namely, the Y-axis in the figure.

Thus, with respect to each set of four through-vias that are connected to one another, only one of the through-vias is connected to an I/O circuit in the semiconductor chip package, similarly to the semiconductor chip package 400 of the embodiment of FIG. 4.

Accordingly, every set of four conductive through-vias that are connected electrically to one another form a signal transmission line. Therefore, in the example illustrated in FIG. 5, eight respective signal transmission lines extend from the semiconductor substrate through the first to fourth layers 510 to 540, and are connected electrically to the I/O circuits 512, 514, 522, 524, 532, 534, 542, and 544 of the first to fourth layers 510 to 540, respectively. Thus, the number of I/O circuits (one) that are connected to each signal transmission line is less than the total number (four) of layers.

Accordingly, in the semiconductor package 500, the number of I/O circuits (one) connected to each transmission line (connected through-vias) is less than the total number of layers (four). Accordingly, the number of I/O circuits connected to a transmission line in the semiconductor chip package 500 is ¼ the number of I/O circuits that would be connected to a transmission line in a semiconductor chip package having conventional TSV architecture. Accordingly, in the semiconductor chip package 500, parasitic capacitance generated due to the I/O circuits 512 to 544 is minimized to maximize the transmission bandwidth of a data bus, for example, formed by the first to fourth through-vias 517a to 547h. Also, the number of I/O circuits of each of the first to fourth layers 510 to 540 is less than that in a corresponding semiconductor chip package having conventional TSV architecture.

Therefore, the embodiment of FIG. 5 provides the same advantages as the embodiments of FIGS. 3 and 4, and encompasses variations similar to those described above with respect to the illustrated examples of the embodiments of FIGS. 3 and 4.

Specifically, as to these variations, the inventive concept is not limited to the orientation of the first to fourth layers 510 to 540 illustrated in FIG. 4. For example, in another example of the semiconductor chip package 500 according to the inventive concept, the structure of the second layer 520 may be the same as that of the first layer 510 but flipped over about a horizontal axis (the Y-axis on the figure), the structure of the third layer 530 may be the as that of the first layer 510 but rotated by 180° counterclockwise or clockwise in a horizontal plane, and the structure of the fourth layer 540 may be the same as that of the first layer 510 but flipped over about the X-axis.

Also, in another example of the semiconductor chip package 500 of the embodiment of FIG. 5, the fourth layer 540, the second layer 520, the third layer 530, and the first layer 510 are stacked in the foregoing order on a semiconductor substrate.

Also, as was mentioned above, the embodiment of FIG. 5 is not limited to a semiconductor chip package in which each of the first to fourth layers 510 to 540 has only two I/O circuits. For example, each of the first to fourth layers 510 to 540 may include four I/O circuits, and the first, second, fifth and sixth through-vias of each layer (or any four vias of the layer, for that matter) may be connected to the four I/O circuits, respectively, of the layer. In this case, compared to a semiconductor chip package having conventional TSV architecture, ½ the number of I/O circuits are connected to each signal transmission line (each set of connected through-vias).

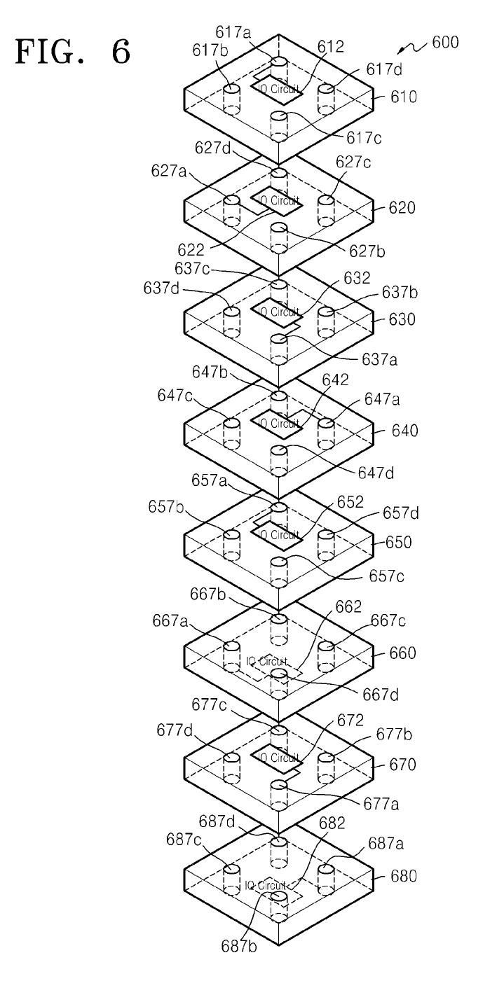

Another embodiment of a semiconductor chip package 600 according to the inventive concept will now be described with reference to FIG. 6. In this example, the semiconductor chip package 600 includes first to eighth layers 610 to 680. The first to eighth layers 610 to 680 may be stacked in the foregoing order on a semiconductor substrate (not shown) of the type shown in and described above with reference to FIGS. 1 and 2.

The semiconductor substrate and the first to eighth layers 610 to 680 may be dies or wafers. For example, the semiconductor substrate and the first to eighth layers 610 to 680 may be a die stack or a wafer stack. Alternatively, the semiconductor substrate may be a wafer and the first to eighth layers 610 to 680 may be dies stacked on the semiconductor substrate. In this case, the semiconductor substrate and the first to eighth layers 610 to 680 constitute a die to wafer stack.

Referring to FIG. 6, in this example, the first to fourth layers 610 to 640 are similar to the first to fourth layers 310 to 340 of the semiconductor chip package 300 of FIG. 3, and the fifth to eighth layers 650 to 680 are similar to the first to fourth layers 410 to 440 of the semiconductor chip package 400 of FIG. 4. That is, the semiconductor package 600 of FIG. 6 may be a combination of the semiconductor package 300 of FIG. 3 and the semiconductor package 400 of FIG. 4.

Therefore, each of the first to eighth layers 610 to 680 includes a carrier body, at least one semiconductor IC supported by the carrier body, at least one I/O circuit (I/O circuits 612, 622, . . . 682, respectively) also supported by the carrier body and each connected to an IC, and first to fourth through-vias (first vias 617a, 627a, . . . 687a, respectively, second vias 617b, 627b, . . . 687b, respectively, third vias 617c, 627a, . . . 687c, respectively, and fourth vias 617d, 627d, . . . 687d, respectively). The other features and advantages of this embodiment will be apparent from the descriptions of the embodiments of FIGS. 3 and 4. Therefore, such features and advantages will not be described in detail for the sake of brevity. Furthermore, the embodiment of FIG. 6 encompasses variations similar to those described above with respect to the illustrated examples of the embodiments of FIGS. 3 and 4. That is, the embodiment of FIG. 6 is not limited to the orientation of layers, sequence in which the layers are stacked, number of I/O circuits per layer, spacing between layers shown in the figure. Thus, such variations also will not be described in detail for the sake of brevity.

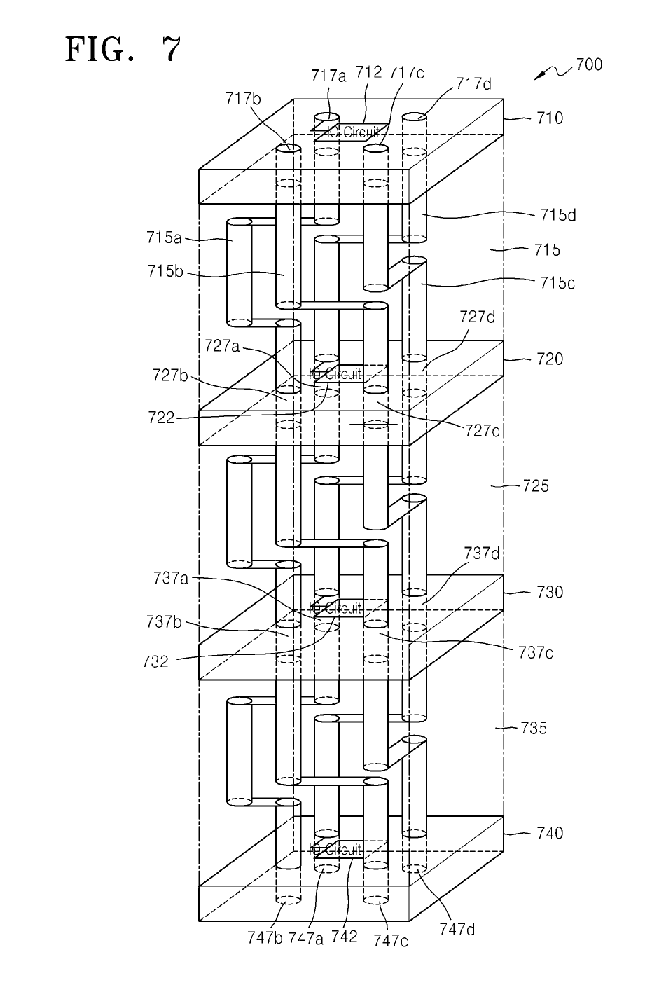

Another embodiment of a semiconductor chip package 700 according to the inventive concept will now be described with reference to FIG. 7.

The semiconductor chip package 700 includes a first layer 710, a second layer 720, a third layer 730, and a fourth layer 740. The fourth layer 740, the third layer 730, the second layer 720, and the first layer 710 are stacked in the foregoing order on a semiconductor substrate.

The semiconductor substrate and the first to fourth layers 710 to 740 may be dies or wafers. For example, the semiconductor substrate and the first to fourth layers 710 to 740 may be a die stack or a wafer stack. Alternatively, the semiconductor substrate may be a wafer and the first to fourth layers 710 to 740 may be dies stacked on the semiconductor substrate. In this case, the semiconductor substrate and the first to fourth layers 710 to 740 constitute a die to wafer stack.

In the semiconductor chip package 700 of FIG. 7, each of the first to fourth layers 710 to 740 includes a carrier body, at least one IC supported by the carrier body, at least one I/O circuit (I/O circuit 712, 722, 732 or 742) also supported by the carrier body and each connected to an I/C, and a plurality of through-vias (first through-via 712a, 722a, 732a or 742a, second through-via 712b, 722b, 732b or 742b, third through-via 712c, 722c, 732c or 742c, and fourth through-via 712d, 722d, 732d or 742d).

In the illustrated example of the embodiment of FIG. 7, as referred to above, each of the first to fourth layers 710 to 740 only one I/O circuit and four through-vias, the inventive concept is not so limited. Rather, each of the first to fourth layers 710 to 740 may include a plurality of I/O circuits, in which case respective ones of the through-vias in each layer are connected to the I/O circuits, respectively, of the layer. Such a variation has been described above in connection with the embodiments of FIGS. 1 to 6, and will not be referred to again herein.

In this embodiment, the first to fourth layers 710 to 740 all have the same structure, i.e., have all the same features/components and orientations. Thus, the first through-vias 717a to 747a are vertically aligned, the second through-vias 717b to 747b are vertically aligned, the third through-vias 717c to 747c are vertically aligned, and the fourth through-vias 717d to 747d are vertically aligned. However, the semiconductor chip package 700 also has first to third redistribution layers 715, 725, and 735 interposed between the first to fourth layers 710 to 740, for the reasons described below.

The first redistribution layer 715 has an interposer body, and redistribution lines 715a, 715b, 715c, and 715d extending through the interposer body. The redistribution lines 715a, 715b, 715c, and 715d connect the first to fourth through-vias 717a to 717d of the first layer 710 to the first to fourth through-vias 727a to 727d of the second layer 720.

More specifically, each redistribution line 715a, 715b, 715c, and 715d connects a respective one of the first to fourth through-vias 717a to 717d of the first layer 710 with a respective one of the first to fourth through-vias 727a to 727d of the second layer 720 which is not vertically aligned with the former, i.e., which is offset from the former in the horizontal direction. For example, the redistribution line 715a connects the first through-via 717a of the first layer 710 to the second through-via 727a of the second layer 720, rather than the first through-via 727a which is vertically aligned with the first through-via 717a. The other through-vias are similarly connected to one another by the redistribution lines.

As a result, in the semiconductor chip package 700 of FIG. 7, with respect to each set of four through-vias that are connected to one another, via one of the redistribution lines, only one of the through-vias is connected to the I/O circuit of its layer. For example, referring to FIG. 7, the first through-via 717a of the first layer 710, the second through-via 727b of the second layer 720, the third through-via 737c of the third layer 730, and the fourth through-via 747d of the fourth layer 740 are connected to one another by the redistribution line 715a. Of these through-vias, the first through-via 717a is connected to the I/O circuit 712 but the second through-via 727b is not connected to the I/O circuit 722, the third through-via 737c is not connected to the I/O circuit 732, and the fourth through-via 747d is not connected to the I/O circuit 742.

Also, in this example, each set of four through-vias and the redistribution line that connect the through-vias form a conductive path, i.e., a signal transmission line to/from the substrate. Thus, the semiconductor substrate and (the semiconductor ICs of) the first to fourth layers 710 to 740 are connected to one another along four discrete (electrically isolated) signal transmission lines. That is, the four transmission lines are connected to the I/O circuits 712, 722, 732, and 742 of the first to fourth layers 710 to 740, respectively.

Thus, the number of I/O circuits connected to each signal transmission line is less than the number of layers of the package. In this example, the number of I/O circuits connected to each set of four through-vias, that are connected to one another by a redistribution line in the semiconductor chip package 700, is ¼ that in a corresponding semiconductor chip package having conventional TSV architecture.

Also, as was the case with the previous embodiments, the embodiment of FIG. 7 is not limited to a semiconductor chip package 700 in which each of the first to fourth layers 710 to 740 has only one I/O circuit. For example, each of the first to fourth layers 710 to 740 may include two I/O circuits, and the first through-via 717a, 727a, 737a, or 747a and the second through-vias 717b, 727b, 737b, or 747b of each layer may be connected to the I/O circuits, respectively, of the layer. In this case, the number of I/O circuits connected to the four connected through-vias is ½ times than in the conventional semiconductor chip package.

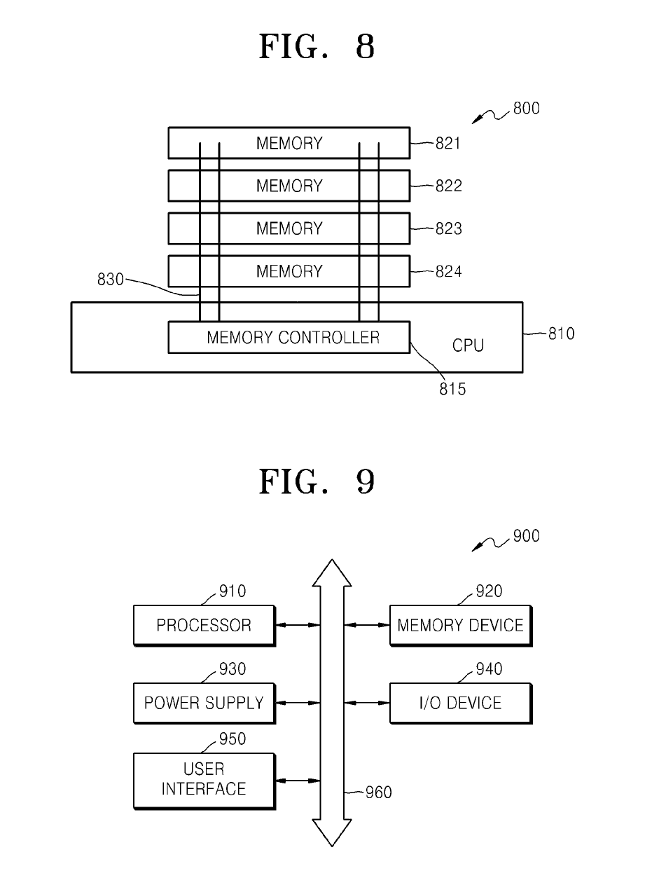

Another embodiment of a semiconductor chip package 800 according to the inventive concept will now be described with reference to FIG. 8.

The semiconductor chip package 800 has a central processing unit (CPU) 810, and a plurality of memory units 821, 822, 823, and 824 stacked on the central processing unit (CPU) 810. The CPU 810 includes a memory controller 815 to which the memory units 821, 822, 823, and 824 are connected via a plurality of through-vias 830. The memory units 821, 822, 823, and 824 may be constituted by the layers of any of the semiconductor chip packages 100, 200, 300, 400, 500, 600, and 700 described above with reference to FIGS. 1 to 7.

A computing system 900 according to the inventive concept will now be described with reference to FIG. 9. The computing system 900 includes a processor 910, a memory device 920, a power supply 930, an input/output (I/O) device 940, and a user interface unit 950. The processor 910, the memory device 920, the I/O device 940, and the user interface unit 950 communicate with one another via a bus 960.

In the computing system 900, the processor 910 and the memory device 920 are constituted by a semiconductor chip package according to the inventive concept, and having features similar to any of those described above with reference to FIGS. 1 to 7. Also, the memory device 920 may be disposed on the processor 920 as described above with reference to FIG. 8.

The processor 910 executes a program to control the computing system 900. The memory device 920 stores code and data for operating the processor 910. Data may be input to or may be output from the computing system 900 via the I/O device 940. The specifics of the structures and operations of the power supply 930 and the user interface unit 950 are conventional, per se, and will not be described in detail here.

The computing system 900 may be used in any type of electronic device that requires a memory. For example, the computing system 900 may be used in computers, mobile phones, MP3 players, navigation devices, solid state disks (SSDs), or home appliances. In the case in which the computing system 900 is used in a mobile device, the power supply 130 is a battery.

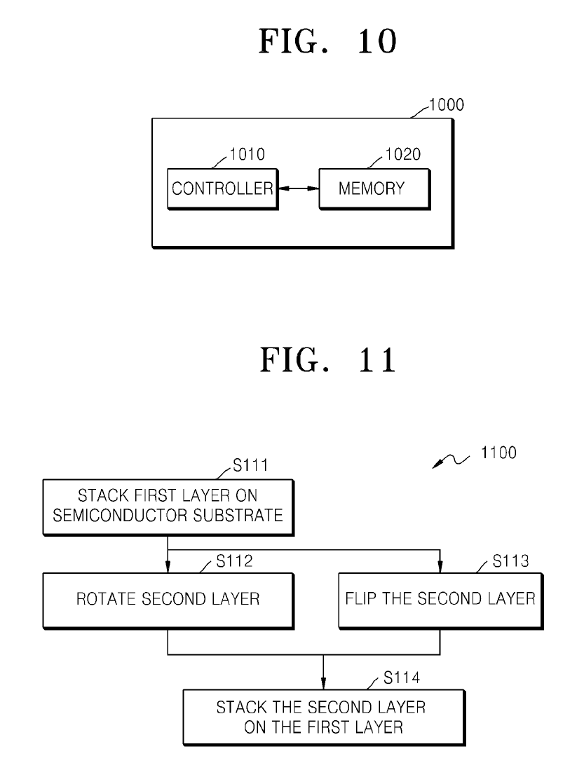

A memory card 1000 according to the inventive concept will be described with reference to FIG. 10. The memory card 1000 may be used as a data storage medium for various types of mobile devices. Examples of the memory card 1000 may include a multi media card (MMC) and a secure digital (SD) card.

The memory card 1000 includes a controller 1010 and a memory unit 1020. The memory unit 1020 may comprise a flash memory, a phase change random access memory (PRAM), or a non-volatile memory. The controller 1010 controls data to be input to or to be output from the memory unit 1020. Accordingly, in the memory card 1000, data may be stored in the memory unit 1020 or may be transmitted from the memory unit 1020 to the outside.

In the memory card 1000, the controller 1010 and the memory unit 1020 are constituted by a semiconductor chip package according to the inventive concept, and having features of any of the embodiments described with reference to FIGS. 1 to 7. Also, the memory device 1020 may be disposed on the controller 1010 as described above with reference to FIG. 8.

Thus, such a memory card 1000 according to the inventive concept may have a relatively great memory capacity and increased functionality. Also, by keeping the interconnection length thereof to a minimum according to the inventive concept, the thickness of the memory card 1000 may be kept to a minimum, and the performance of the memory card 1000 may be enhanced.

FIG. 11 illustrates an embodiment of a method 1100 of fabricating a semiconductor chip package, according to the inventive concept.

Referring to FIG. 11, the method 1100 includes providing identical first and second layers. As described above, each of the first and second layers includes a carrier body, a semiconductor IC and an I/O circuit connected to one another and supported by the carrier body (at least one each), and a plurality of through-vias extending through the carrier body as electrically isolated from one another. Each semiconductor IC and I/O circuit is formed at an upper surface of the carrier body. The through-vias may be TSVs. One of the through-vias is connected to the I/O circuit, whereas each other through-via is not connected to the I/O circuit.

In this step, therefore, the layers are fabricated according to a via-first process. Also, the IC (or ICs) and the I/O circuit (or circuits) may be formed on the carrier body of each of the layers by fabrication techniques known, per se. In the case in which the layers are dies, for example, ICs and I/O circuits are formed on a wafer and the wafer is then sliced into individual dies that bear an IC (or ICs) and an I/O circuit (or circuits).

Also, as should be clear from any of FIGS. 1-7, the through-vias have a symmetry about a vertical axis (an axis perpendicular to the layer) which allows the through-vias to collectively occupy the same place in space regardless of whether the layer is rotated any increment of 90° about the vertical axis. Likewise, the through-vias have a symmetry about a horizontal axis parallel to the layer (or about each of two orthogonal horizontal axes) so that the through-vias can collectively occupy the same space regardless of whether the layer is right side up or has been flipped over about one of the horizontal axes. Although not shown in the drawings, the locations of these axes, as superimposed on the second layer, would be apparent to those skilled in the art.

Next, the first layer is stacked on a semiconductor substrate (S111). The substrate may be of the type described with reference to FIGS. 1 and 2. At this time, the through-vias of the first layer may be electrically connected to electrodes, e.g., conductive pads, of the semiconductor substrate.

Next, the second layer is rotated (S112) or flipped over (S113). This step could also precede step S111 in the fabrication process.

In any case, if it is determined that the second layer should be rotated, then the second layer is rotated about a centrally located vertical axis (i.e., in a horizontal plane) by 90°, 180°, or 270° counterclockwise.

On the other hand, if it is determined that the second layer should be flipped over, then the second layer is rotated by 180° about a horizontal axis on opposite sides of which equal numbers of the through-vias are provided.

In this state, the second layer is stacked on the first layer (S114). As a result, the through-vias of the second layer are vertically aligned with the through-vias of the first layer, respectively. The stacking process may also electrically connect the through-vias of the first layer to the through-vias of the second layer. Note, in this respect, S112 or S113 may be carried out to ensure that the through-via of the first layer which is connected to the I/O circuit of the first layer is not vertically aligned with and connected to that through-via of the second layer which is electrically connected to the I/O circuit of the second layer.

Furthermore, although the method has been described above with respect to a via-first process (applicable to the fabrication of the embodiments of FIGS. 1-6), a chip package of the type shown in FIG. 7 may be fabricated instead by a method according to the inventive concept using a via-middle process in a way that would be readily apparent to those of ordinary skill in the art and thus, will not be described in detail here.

In any case, the advantages of a semiconductor chip package fabricated by the method according to the inventive concept have been described above with reference to FIGS. 1 to 7 and will not be described in detail again here.

Finally, embodiments of the inventive concept have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiments described above but by the following claims.

What is claimed is:

1. A semiconductor chip package comprising:
a first layer including a first carrier body, a first input/output (I/O) circuit, a first electrically conductive through-via extending through the first carrier body and electrically connected to the first input/output (I/O) circuit, and a second electrically conductive through-via extending through the first carrier body as electrically isolated from the first I/O circuit; and
a second layer disposed on the first layer, the second layer including a second carrier body, a second input/output (I/O), a third electrically conductive through-via via extending through the second carrier body and electrically connected to the second I/O circuit, and a fourth electrically conductive through-via extending through the second carrier body as electrically isolated from the second I/O circuit,
wherein the first through-via of the first layer is electrically connected to the fourth through-via, and the second through-via of the first layer is electrically connected to the third through-via.

2. The semiconductor chip package of claim 1, wherein the structure of the second layer is substantially the same as that of the first layer but rotated by 90°, 180°, or 270° in a plane parallel to that of the layers.

3. The semiconductor chip package of claim 1, wherein the structure of the second layer is substantially the same as that of the first layer but flipped over.

4. The semiconductor chip package of claim 1, wherein each of the layers comprises a wafer or a die, and the through-vias are through-silicon vias (TSVs).

5. The semiconductor chip package of claim 1, further comprising a semiconductor substrate on which the first layer is disposed.

6. The semiconductor chip package of claim 5, wherein the semiconductor substrate comprises an insulating body having an upper surface and a lower surface, conductive terminals at the upper surface of the insulating body and disposed in contact with the through-vias of the first layer, and external terminals that are exposed at the outside of the semiconductor substrate and are electrically connected to the conductive terminals

7. A semiconductor chip package comprising:
a plurality of layers stacked one atop the other,
each of the layers including a carrier body, at least one input/output (I/O) circuit supported by and disposed at a surface of the first carrier body, at least one semiconductor integrated circuit (IC) supported by the carrier body and to each of which a respective said I/O circuit of the layer is electrically connected, and plurality of electrically conductive through-vias extending through the carrier body as electrically isolated from one another, and
wherein the I/O circuit of each layer is electrically connected to a respective one of the through-vias of the layer,
each of the through-vias of one of the layers is electrically connected to one of the through-vias of each of the other layers, such that the layers have sets of electrically connected through-vias, and each of the sets of electrically connected through-vias constitutes a respective signal transmission line in the package,
each of the I/O circuits is electrically connected to one of the signal transmission lines, and
wherein the total number of said I/O circuits connected to each of the signal transmission lines is less than the total number of said layers constituting the package.

8. The semiconductor chip package of claim 7, wherein each of the layers comprises a wafer or a die, and the through-vias are through-silicon vias (TSVs).

9. The semiconductor chip package of claim 7, wherein the through-vias of each layer are disposed symmetrically about an axis perpendicular to the layer.

10. The semiconductor chip package of claim 8, wherein the through-vias of each layer are disposed in groups of four arranged at equal angular increments of 90° about the axis.

11. The semiconductor chip package of claim 10, wherein the structure of one of the layer is substantially the same as that of another of the layers but rotated by 90°, 180°, or 270° about the axis.

12. The semiconductor chip package of claim 7, wherein the through-vias of each layer are disposed symmetrically about an axis parallel to the layer.

13. The semiconductor chip package of claim 12, wherein the structure of one of the layers is substantially the same as that of another of the layers but flipped over about the axis.

14. The semiconductor chip package of claim 7, wherein the through-vias of each layer are disposed symmetrically about each of two axes orthogonal to each other and parallel to the layer.

15. The semiconductor chip package of claim 14, wherein the structure of one of the layers is substantially the same as that of the other of the layers but flipped over about one of the axes.

16. The semiconductor chip package of claim 7, wherein each of the I/O circuits comprises an input buffer and an output driver.

17. The semiconductor chip package of claim 7, wherein the through-vias of the layers together constitute a data bus or a command/address bus.

18. The semiconductor chip package of claim 7, wherein each of the through-vias of one of the layers is aligned with and electrically connected to respective ones of the through-vias of the other layers.

19. The semiconductor chip package of claim 7, further comprising redistribution layers including a series of conductive redistribution lines extending between the layers of each adjacent pair thereof, and
wherein each through-via of one of the adjacent pair of layers is electrically connected to one of the through-vias of the other of the adjacent pair of layers by a respective one of the redistribution lines whereby each set of through-vias and the redistribution line that electrically connects the through-vias of the set together constitute a respective one of the signal transmission lines, and
the through-vias in the adjacent pair of layers that are electrically connected to each other by a redistribution line are offset from one another in a plane parallel to the layers.

20. The semiconductor chip package of claim 7, wherein each of the layers has a plurality of I/O circuits.

21. The semiconductor chip package of claim 7, further comprising a semiconductor substrate on which the layers are disposed, the semiconductor substrate comprising an insulating body having an upper surface and a lower surface, conductive terminals at the upper surface of the insulating body and disposed in contact with the through-vias of one of the layers, and external terminals that are exposed at the outside of the semiconductor substrate and are electrically connected to the conductive terminals.

22. The semiconductor chip package of claim 7, further comprising a central processing unit (CPU) on which the layers are disposed and having circuitry to which the through-vias of the layers are electrically connected.

23. An electronic device comprising a semiconductor chip package as claimed in claim 7, a user interface, and a power supply, wherein the semiconductor chip package constitutes a processor and a memory of the electronic device.

24. A memory card comprising a controller and a memory constituted by a semiconductor chip package as claimed in claim 7.

25. A method of fabricating a semiconductor chip package, the method comprising:
forming first and second layers having substantially the same structures wherein the first layer comprises a carrier body, a first input/output (I/O) circuit of the package, and a semiconductor integrated circuit (IC) to which the first I/O circuit is electrically connected, and the second layer comprises a carrier body, a second input/output (I/O) circuit of the package, and a semiconductor integrated circuit (IC) to which the second I/O circuit is electrically connected; and
electrically connecting the first and second layers to each other by forming a plurality of through-vias through the carrier body of each layer such that one of the through-vias of each layer is connected to the I/O circuit of the layer whereas each other through-via of the layer is electrically isolated from the I/O circuit of the layer,
the through-vias of the first layer are electrically connected to the through-vias of the second layer, respectively, and
the through-via of the first layer that is electrically connected to the first I/O circuit is electrically connected to a through-via of the second layer that is electrically isolated from the second I/O circuit.

26. The method of claim 25, wherein the connecting of the first and second layers comprises stacking the first layer on a substrate, and stacking the second layer on the first layer.

27. The method of claim 26, wherein the through-vias are formed in groups of four arranged at equal angular increments of 90° about an axis, and further comprising rotating the second layer by 90°, 180°, or 270° counterclockwise in a plane parallel to the second layer before the second layer is stacked on the first layer.

28. The method of claim 26, wherein in each layer the through-vias are formed symmetrically about an axis parallel to the layer, and further comprising flipping the second layer over before the second layer is stacked on the first layer.
